(19) United States
(12) Patent Application Publication
(10) Pub. No.: US 2011/0101409 A1
(43) Pub. Date: May 5, 2011

(54) LED Lamp Package with Integral Driver

(75) Inventor: Thomas J. Barnett, POWELL, OH (US)

(73) Assignee: AKRON BRASS COMPANY, COLUMBUS, OH (US)

(21) Appl. No.: 12/916,698

(22) Filed: Nov. 1, 2010

Related U.S. Application Data
(60) Provisional application No. 61/257,295, filed on Nov. 2, 2009.

(51) Int. Cl. H01L 33/00; H01L 23/00

(52) U.S. Cl. 257/99; 438/26; 257/E33.058; 257/E23.001

(57) ABSTRACT

A lamp package includes a leadframe. At least one light emitting diode is mechanically and electrically coupled to the leadframe. At least one electronic component is also mechanically and electrically coupled to the leadframe and electrically coupled to the light emitting diode, the electronic component controlling the supply of electrical power to the light emitting diode. At least one interconnect is electrically coupled to the leadframe. A formed structure is joined to the leadframe, the formed structure enclosing at least a portion of the leadframe.

This application claims priority to U.S. provisional patent application No. 61/257,295, filed Nov. 2, 2009, the entire contents of which are hereby incorporated by reference.

### FIELD

The present invention relates generally to light emitting diodes (LEDs), in particular to an LED lamp package having an integral driver to control the supply of energy to the LED.

### BACKGROUND

Solid-state lamp assemblies generally include packaged LEDs or unpackaged “chip” LEDs that are coupled to a printed circuit board (PCB). The PCB is often populated with several other electronic devices to control the energy (e.g., voltage and/or current) delivered to the LEDs. The electronic components can range from simple resistors and diodes up to and including complex discrete and/or integrated circuits such as buck/boost constant-current drivers. The PCB is usually also populated with either terminals or wires as an electrical interface means to supply power to the circuit. The PCB assembly is then packaged into a housing generally consisting of a lens and a base, the finished product forming a lamp assembly. In order to reduce the cost and complexity of the lamp assembly it is desirable to combine as many components as possible into a unitary lamp package.

### SUMMARY

An LED lamp package having an integral LED driver is disclosed according to an embodiment of the present invention. The lamp package comprises a leadframe to which one or more LEDs are attached. The leadframe further includes electrical connections to the LEDs. In some embodiments of the present invention the lamp package may include most or all of the electronic components, a housing, a mount, lensing/optics and an electrical connector, resulting in a complete lamp assembly.

In one embodiment at least a portion of the leadframe is molded or cast prior to assembling the electronic components and/or LEDs to an exposed portion of the lamp package. The exposed portion is closed off with a sealant after assembly. Alternatively, some or all of the electronic components may be assembled to the leadframe prior to molding or casting. The molding/casting operation encapsulates the components, eliminating the need to perform the secondary potting operations. A portion or the entire rear surface of the metal leadframe may be exposed in a manner similar to a typical “TO-220” semiconductor package.

In addition, the arrangement of the LEDs and leadframe allows the leadframe package to be configured to accommodate the electrical attachment(s) of the various components. Example configurations include single function (e.g., for use in a vehicle marker lamp) and multi-function (e.g., for use in a vehicle brake/tail lamp, brake/turn signal lamp “dual color”, etc.).

In an embodiment of the present invention a lamp package includes a leadframe. At least one light emitting diode is mechanically and electrically coupled to the leadframe. At least one electronic component is also mechanically and electrically coupled to the leadframe and electrically coupled to the light emitting diode, the electronic component controlling the supply of electrical power to the light emitting diode. At least one interconnect is electrically coupled to the leadframe. A formed structure is joined to the leadframe, the formed structure enclosing at least a portion of the leadframe.

### BRIEF DESCRIPTION OF THE DRAWINGS

Further features of the inventive embodiments will become apparent to those skilled in the art to which the embodiments relate from reading the specification and claims with reference to the accompanying drawings, in which:

FIG. 1 shows a lamp package according to an embodiment of the present invention;

FIG. 2 shows a leadframe according to an embodiment of the present invention;

FIG. 3 shows packaged electronic components assembled to the leadframe of FIG. 2;

FIG. 4 shows formed structures overmolded to the leadframe of FIG. 2;

FIG. 5 shows LED chip components assembled to the leadframe of FIG. 2;

FIG. 6 shows cavities of the formed structures of FIG. 4 filled with a sealant material;

FIG. 7 shows a finished package separated from the leadframe of FIG. 2 and into an individual package;

FIG. 8 is a flow diagram of a process for making a lamp package according to an embodiment of the present invention;

FIG. 9 is a flow diagram of a process for making a lamp package according to another embodiment of the present invention;

FIG. 10 is a flow diagram of a process for making a lamp package according to yet another embodiment of the present invention;

FIG. 11 is a flow diagram of a process for making a lamp package according to still another embodiment of the present invention;

FIG. 12 is a flow diagram of a process for making a lamp package according to yet another embodiment of the present invention;

FIG. 13 is a flow diagram of a process for making a lamp package according to still another embodiment of the present invention;

FIG. 14 shows a lamp package according to an alternate embodiment of the present invention;

FIG. 15 shows the lamp package of FIG. 14 without a support structure; and

FIG. 16 shows an exposed portion of the lamp package of FIG. 14.

### DETAILED DESCRIPTION

In the discussion that follows, like reference numerals are used to refer to like elements and structures in the various embodiments and figures.

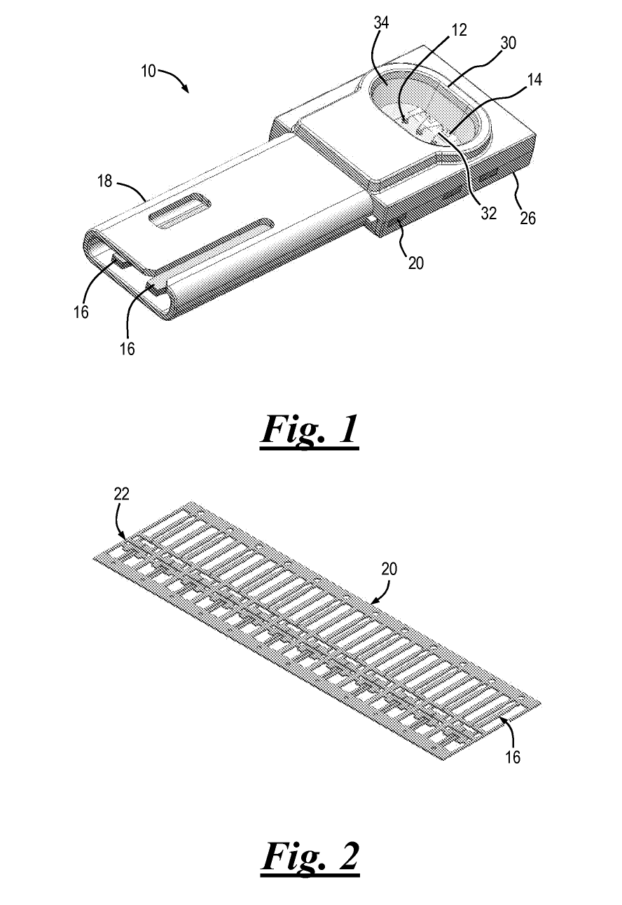

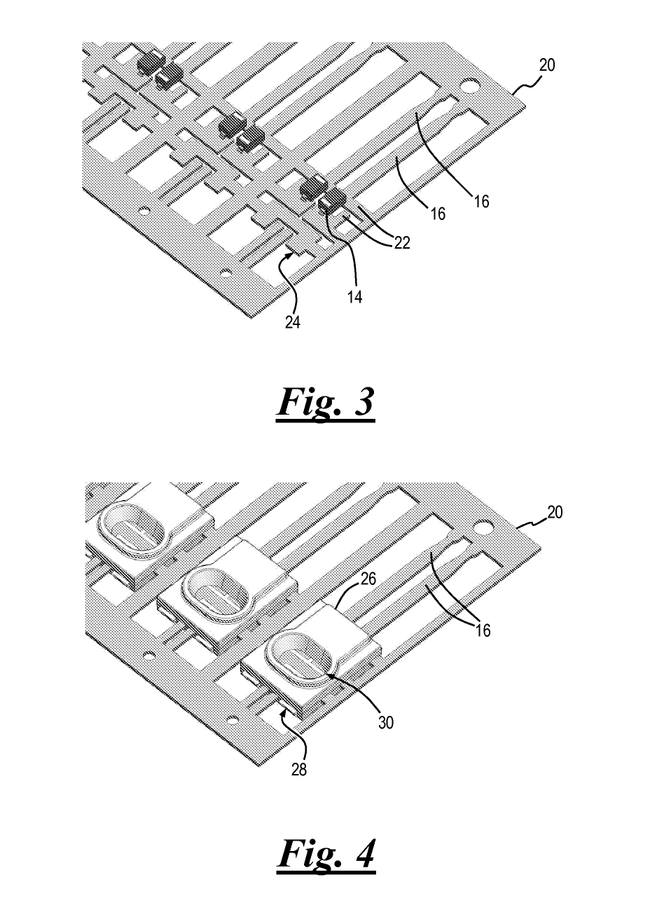

With reference to FIG. 1, in a first embodiment of the present invention a lamp package 10 contains one or more LEDs 12. Disposed in lamp package 10 is one or more electronic components 14 (FIG. 3) in packaged and/or chip form to control the supply of electrical power to LED 12. Extending away from lamp package 10 is one or more interconnects 16 for coupling a source of electrical power (not shown) to the lamp package. In some embodiments lamp package 10 may include a suitable connector geometry 18 proximate interconnects 16 for coupling the lamp package to a mating connector (not shown).

LED 12 may be provided in chip and/or packaged form. In addition, LED 12 may be selected from various types of LED elements including, without limitation, single-color LEDs, multi-color LEDs, and LEDs coupled with a light converting material such as phosphor. The selection of LED 12 from these various elements is typically defined by the application in which lamp package 10 is used, such as a vehicle brake lamp, a vehicle interior dome lamp, and a color-changing lamp, among others.

Electronic components 14 may also be provided in chip and/or packaged form. Electronic components 12 may be any type of suitable electronic components now known or later invented. Example electronic components 12 include, without limitation, discrete switches, resistors, diodes, capacitors, inductors and semiconductors as well as integrated circuits comprising a predetermined combination of the aforementioned electronic components.

Electronic components 14 may be configured to form any type of light emitting diode current and/or voltage power control circuit or ancillary circuit now known or later invented. In addition, electronic components 14 may be configured to provide functions such as, but not limited to, buck/boost converters, compensation for LED light output degradation over life, fault “flag” signal outputs, on/off control, duty cycle control, remote control, light output (i.e., dimming) control, interfaces with networks such as CAN bus, redundancy, and automatic fault correction.

Interconnects 16 may be round, square or rectangular pins that are sized and shaped for in-line applications. Alternatively, lamp package 10 may include several interconnects 16 extending from the lamp package for coupling to other devices. In still other embodiments interconnects 16 may be exposed terminals configured to mate with an electrical connector. Interconnects 16 may also be exposed to facilitate attaching secondary interconnects such as wires, springs and additional terminals. These secondary interconnects may be attached by means of soldering, welding, clinching/staking, adhering or any other means available.

Connector geometry 18 may be, without limitation, an automotive-style connector, a USB-style connector or any other connector sized and shaped for electrically coupling lamp package 10 to a mating connector of another device or an electrical power source. Connector geometry 18 may optionally include features such as keyed or polarizing shapes, weatherproofing, a select gender, and locking features for selectably and detachably securing lamp package 10 to a mating connector.

In one embodiment of the present invention, shown in FIGS. 2 through 7, lamp package 10 may include a leadframe 20 (FIGS. 2 and 3). Leadframe 20 provides both a mechanical support structure and electrical interconnections for LEDs 12 and electronic components 14. In some embodiments leadframe 20 may include integrally formed interconnects 16. In some embodiments interconnects 16 are formed as exposed tabs or contact springs as part of leadframe 20.

Leadframe 20 may be made from any suitable conductive material including, but not limited to, copper alloys. In addition, leadframe 20 may be finished in any suitable manner such as by plating with materials such as silver, gold and tin. Leadframe 20 may be produced by stamping, etching, casting, laser or water-jet cutting, or any other method suitable for providing metal in a predefined pattern. Leadframe 20 may be produced individually for a single lamp package 10, or may be made for assembly of plural lamp packages as a unit as shown in FIGS. 2 through 6, the lamp packages being separable during or after assembly.

Electronic components 14 are assembled to predetermined connection points 22 of leadframe 20 (FIG. 3). Assembly of chip electronic components may be made via wire bonding, “flip chip,” soldering or any other means suitable for providing electrical connectivity. Alternately, some or all of the electronic components 14 may be packaged parts. The packaged electronic components 14 may be mechanically and electrically coupled to leadframe 20 by means of soldering, welding, clinching/staking, adhesives or any other suitable means.

The resulting leadframe assembly 24 (FIG. 3), comprising electronic components 14 assembled to leadframe 20, is then overmolded with a formed structure 26 (FIG. 4), resulting in a molded leadframe assembly 28. Formed structure 26 may be made of a plastic, glass, ceramic or any other electrically insulating and moldable or castable material. In some embodiments formed structure 26 is opaque to conceal electronic components 14 from view. Preferably, leadframe assembly 24 includes a cavity 30 that exposes a predetermined portion of leadframe 20.

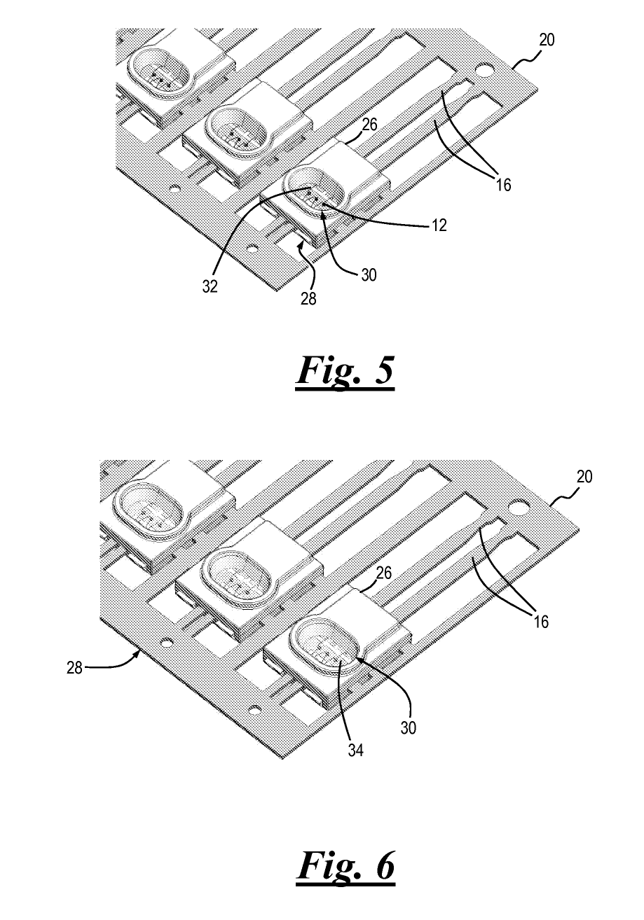

With reference to FIG. 5, LEDs 12 are assembled to predetermined connection points 22 of molded leadframe assembly 28, the LEDs being disposed in cavity 30. The LEDs 12 are attached to predetermined connection points 22 in the connecting points 22 in cavity 30 with a suitable die attach adhesive (not shown) therebetween. Wire bonding 32 is attached between LEDs 12 and the exposed portion of leadframe 20 in cavity 30 to provide electrical connections between the LEDs and the leadframe.

After LEDs 12 are assembled to molded leadframe assembly 28 cavity 30 is closed off with a suitable “potting” sealant material 34 as shown in FIG. 6. Sealant 34 may be a generally clear or transparent material such as silicone, epoxy, plastic resin, glass or any other material now known or later invented for use in potting or casting. Sealant 34 provides environmental protection and structure to cavity 30 of lamp package 10 to resist contamination, moisture, dust, vibration, shock and so on.

Sealant 34 may also be configured to improve light extraction from LED 12 of lamp package 10. Consequently, sealant 34 may be planar, or may be formed/molded into a predetermined lens shape to provide the desired light output characteristics. Example lens shapes may include, but are not limited to, convex, concave, biconvex, biconcave, plano-convex, plano-concave, spherical, positive-meniscus, negative-meniscus and compound lenses. In still other embodiments a pre-shaped lens may be joined to formed structure 26 to close off cavity 30.

Sealant 34 may also include a light excitable material, such as phosphor. This may be desirable for producing multi-chromatic light such as, for example, white light. Sealant 34 may also include light-diffusing and color-shifting materials. Example light-diffusing materials include plastic, glass and metal or metalized particles and polarizers that block and/or redirect light. Example color-shifting materials include inks, colorants, prismatic elements and polarizing elements.

In some embodiments electronic components 14 may be located in cavity 30, allow a single application of sealant 34 to protect both the electronic components and LEDs 12. Alternatively, electronic components 14 may be located in a portion of lamp package 10 separate from cavity 30. This may be advantageous if the identifying marks of electronic components 14 are to be concealed to obscure their identity for the purpose of deterring reverse-engineering. Such areas may be potted with an opaque sealant 34.

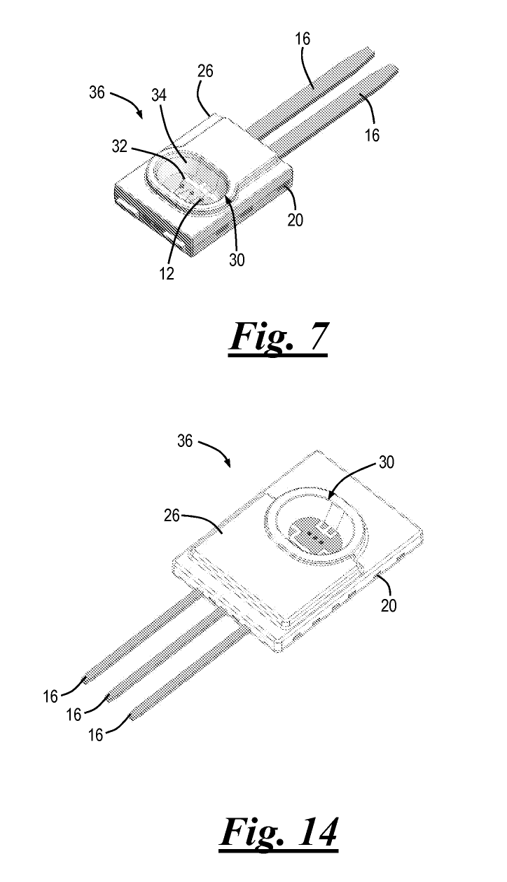

The finished lamp package 10 may then be separated, or “singulated” from the leadframe 20 (FIG. 7). The singulation process separates all of the connecting points 22 and electrical interconnects 16 from leadframe 18 to provide discrete functional circuits.

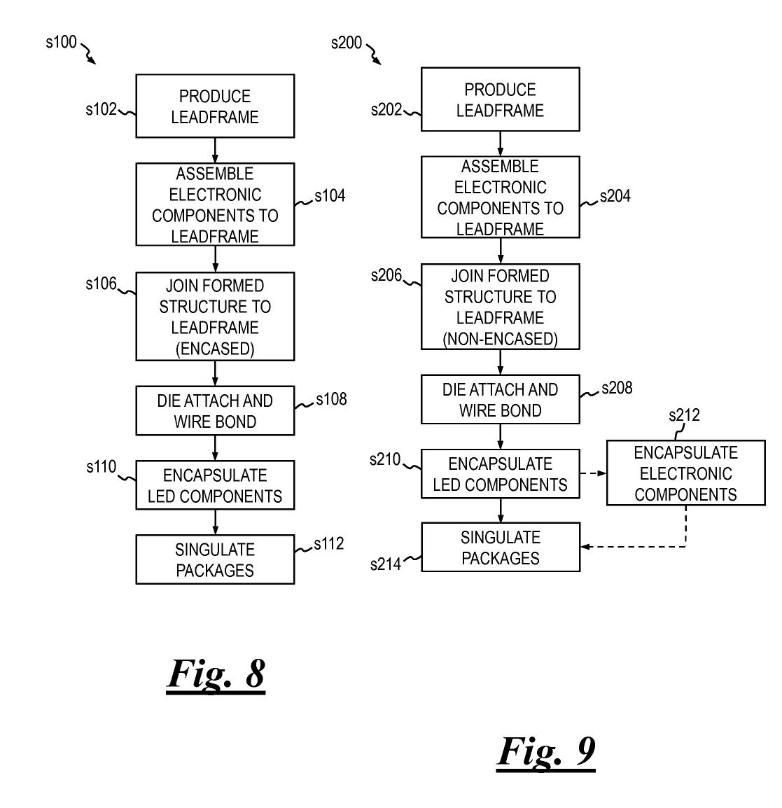

With reference now to FIGS. 2 through 8, in an embodiment of the present invention a method s100 is utilized to produce a lamp package 10 comprising any suitable combination of packaged and/or chip electronic components 14. A leadframe 20 is produced at step s102. Packaged and/or chip electronic components 14 are assembled to leadframe 20 at step s104. A formed structure 26 is joined to leadframe 20 at step s106, encapsulating, covering or at least partially enclosing or covering electronic components 14 and forming cavity 30. At step s108 die attach adhesive (not shown) and wire bond 32 is used to mechanically and electrically couple chip LED components 12 to leadframe 20. At step s110 LED chip components 12 are enclosed, covered or encapsulated using sealant 34. At step s112 the completed lamp packages 10 are singulated.

With reference to FIG. 9, in another embodiment of the present invention a method s200 is utilized to produce a lamp package 10 comprising any suitable combination of packaged and/or chip electronic components 14. At step s202 a leadframe 20 is produced. At step s204 electronic components 14 are assembled to the leadframe 20. A formed structure 26 is joined to the leadframe 20 at step s206. The tooling for formed structure 26 is preferably constructed such that the electronic components 14 are not encased by the formed structure 26. This will reduce stress on electronic components 14 by reducing thermal exposure from the overmolding process and reducing mechanical stress on the electronic components 14 due to thermal expansion and contraction during overmolding or casting. At step s208 die attach adhesive and wire bond 32 is used to interconnect chip LED components 12 and leadframe 20. At step s210 LED chip components 12 are enclosed, covered or encapsulated using sealant 34. The non-encased electronic components 14 are optionally enclosed, covered or encapsulated at step s212 using a suitable material such as, but not limited to, sealant 34. At step s214 the completed lamp packages 10 are singulated.

With reference to FIG. 10, in yet another embodiment of the present invention a method s300 is utilized to produce a lamp package 10 comprising any suitable combination of packaged and/or chip electronic components 14. A leadframe 20 is produced at step s302. At step s304 a formed structure 26 is joined to the leadframe 20. Connection points 22 (FIG. 3) for the electronic components 14 remain exposed on leadframe 20 after formed structure 26 is joined to the leadframe, to allow assembly of the electronic components to the leadframe in a later step. As in method s200, by not encapsulating, covering or enclosing the electronic components 14, less thermal stress is placed on them by the joining of formed structure 26 to the leadframe 20. At step s306 electronic components 14 are assembled to leadframe 20. Die attach adhesive and wire bond 32 are used to mechanically and electrically couple LED chip components 12 to leadframe 20 at step s308. At step s310 LED chip components 12 are encapsulated or at least partially enclosed or covered using sealant 34. The electronic components 14 may optionally be encapsulated, covered or enclosed at step s312 using a suitable material such as, but not limited to, sealant 34. In some embodiments steps s310 and s312 may be combined. At step s314 the completed lamp packages 10 are singulated.

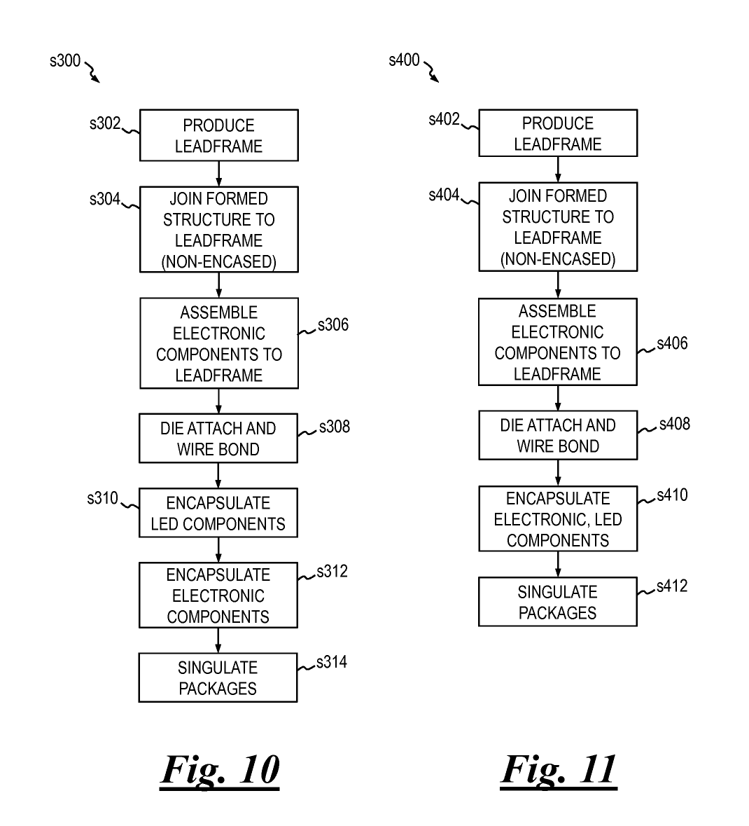

With reference to FIG. 11, in still another embodiment of the present invention a method s400 is utilized to produce a lamp package 10 comprising chip electronic components 14. A leadframe 20 is produced at step s402. A formed structure 26 is joined to the leadframe 20 at step s404. Connection points 22 (FIG. 3) for chip electronic components 14 on leadframe 20 remain exposed after formed structure 26 is joined to the leadframe, to allow assembly of the electronic components to the leadframe in a later step. At step s406 the chip electronic components 14 are assembled to the leadframe 20. Die attach adhesive and wire bond 32 are used to mechanically and electrically couple LED chip components 12 to leadframe 20 at step s408. At step s410 electronic chip components 14 and LED chip components 12 are encapsulated, covered or enclosed using sealant 34. The sealant potting process may include different types of materials for different chips based on their function/purpose. For example, the LED chips 12 are preferably sealed with a clear material while the driver components (e.g., electronic components 14) may be sealed in an opaque material to conceal them from view. At step s412 the completed lamp packages 10 are singulated.

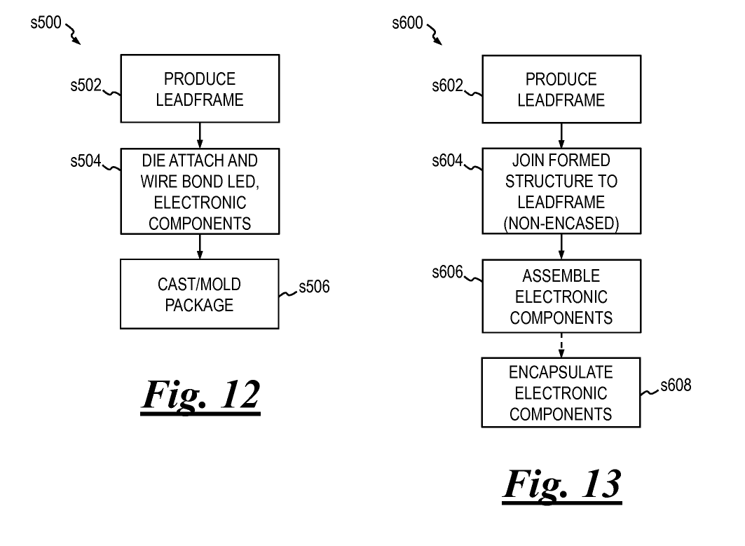

With reference to FIG. 12, in yet another alternate embodiment of the present invention a method s500 is utilized to produce a lamp package 10 comprising chip electronic components 14. At step s502 a leadframe 20 is produced. Die attach adhesive and wire bond 32 are used to mechanically and electrically couple electronic chip components and LED chip components 12 to leadframe 20 at step s504. At step s506 the body of the lamp package is cast and/or molded using the same materials as for formed structure 26 and/or sealant 34. In the case of an LED component 12, the casting/molding material is preferably clear. For non-optical electronic components 14 and/or lamp packages 10 lacking optical devices the material may be opaque.

With reference to FIG. 13, in still another alternate embodiment of the present invention a method s600 is utilized to produce a lamp package 10 comprising chip electronic components 14. A leadframe 20 is produced at step s602. A formed structure 26 is joined to the leadframe 20 at step s604 to form a molded leadframe assembly 28. Connection points 22 for packaged electronic components 14 remain exposed on leadframe 20 after formed structure 26 is joined to the leadframe, to allow assembly of the electronic components to the leadframe at a later step. At step s606 the packaged electronic components 14 are assembled to the molded leadframe assembly 28. At an optional step s608 packaged electronic components 14 may be encapsulated covered or enclosed using sealant 34. The sealant potting process may comprise different types of materials for different chips 12, 14 based on their function/purpose. For example, the LED chips 12 are preferably sealed with a clear material while the driver components (e.g., electronic components 14) may be sealed in an opaque material to conceal them from view.

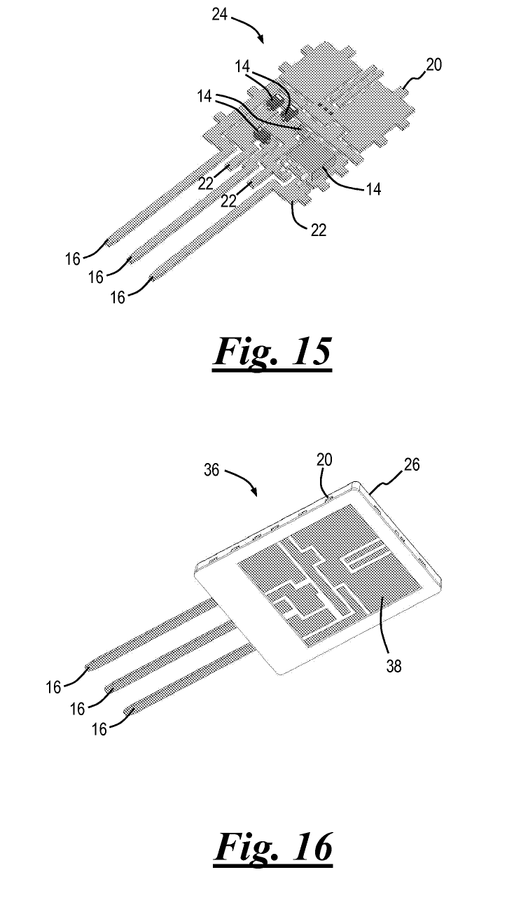

A lamp package 36 having a plurality of interconnects 16 is shown in FIGS. 14 through 16 according to an alternate embodiment of the present invention. FIG. 14 shows lamp package 36 with an overmolded formed structure 26, while FIG. 15 shows the lamp package without the overmolded formed structure.

FIG. 16 shows a rear surface 38 of leadframe 20 of lamp package 36 for heat sinking of the lamp package. In one embodiment a portion or the entire back of rear surface 38 may be exposed in a manner similar to a typical “TO-220” semiconductor package. Also, like the TO-220 package, tabs or other similar appendages may extend beyond the molded body of the lamp package. The purpose of these exposed areas and tabs/appendages is to allow the molded lamp package to be coupled to an external heat sink to improve heat extraction from the lamp package 36.

The heat sinking provided by leadframe 20 may be adjusted to accommodate different power levels required by LED 12 and/or electronic components 14. For lower-power devices, leadframe 20 may be made considerably lighter, thinner and smaller in comparison with higher-power devices. In addition, a rear surface of leadframe 20 may be exposed in the manner previously described, in one or more select areas, to allow thermal coupling of the leadframe to an external heat sink or other mounting device for improved power dissipation of lamp package 36. In addition, a formed structure 26 may be molded onto leadframe 20 utilizing a suitable thermally conductive, electrically insulative material such as is available from Cool Polymers, Inc. of Warwick, RI. One exemplary material is “CoolPoly D-Series” products available from Cool Polymers, Inc.

While the above description details the assembly of an LED lamp package, one skilled in the art will appreciate that other types of electronic packages may also be made in a similar manner. Such electronic devices include but are not limited to, resistors, diodes, transistors, sensors, capacitors, memory devices, and so on. Therefore, it will be understood by those skilled in the art that changes in form and detail thereof may be made without departing from the scope of the claims of the invention.

What is claimed is:

1. A lamp package, comprising:
a leadframe;
at least one light emitting diode mechanically and electrically coupled to the leadframe;
at least one electronic component mechanically and electrically coupled to the leadframe and electrically coupled to the light emitting diode, the electronic component controlling the supply of electrical power to the light emitting diode;
at least one interconnect electrically coupled to the leadframe; and
a formed structure joined to the leadframe, the formed structure enclosing at least a portion of the leadframe.

2. The lamp package of claim 1 wherein the formed structure is made from an opaque material.

3. The lamp package of claim 1, further including a cavity in the formed structure, the leadframe being exposed in the cavity and the light emitting diode being disposed in the cavity.

4. The lamp package of claim 3, further comprising a sealant disposed in the cavity and closing off the cavity.

5. The lamp package of claim 4 wherein the sealant is generally transparent.

6. The lamp package of claim 5 wherein the sealant functions as a lens having predetermined optical characteristics.

7. The lamp package of claim 5 wherein the sealant further includes a light-excitable material.

8. The lamp package of claim 5 wherein the sealant further includes light-diffusing materials.

9. The lamp package of claim 5 wherein the sealant further includes color-shifting materials.

10. The lamp package of claim 1, further including a connector geometry proximate the interconnect.

11. The lamp package of claim 1, further including wire bonding extending between the light emitting diode and the leadframe, the wire bonding electrically coupling the light emitting diode to the leadframe.

12. The lamp package of claim 1 wherein the lamp package comprises a plurality of interconnects.

13. The lamp package of claim 12 wherein at least a portion of a rear surface of the enclosed leadframe is exposed.

14. The lamp package of claim 1 wherein the electronic component is enclosed by the formed structure.

15. The lamp package of claim 1 wherein the electronic component remains exposed after the formed structure is joined to the leadframe.

16. The lamp package of claim 15 wherein the electronic component is enclosed by a sealant.

17. The lamp package of claim 1 wherein the interconnect is integral to the leadframe.

18. A method for making a lamp package, comprising the steps of:
producing a leadframe;
assembling at least one electronic component to the leadframe;
joining a formed structure to the leadframe, the formed structure enclosing the electronic component and including a cavity, the leadframe being exposed in the cavity;
assembling at least one light emitting diode to the exposed leadframe in the cavity; and
closing off the cavity with a generally transparent sealant.

19. A method for making a lamp package, comprising the steps of:
producing a leadframe;
assembling at least one electronic component to the leadframe;
joining a formed structure to the leadframe, the formed structure including a cavity, the leadframe being exposed in the cavity and the electronic components being exposed;
assembling at least one light emitting diode to the exposed leadframe in the cavity; and
closing off the cavity with a generally transparent sealant.

20. The method of claim 12, further including the step of enclosing the electronic components with a sealant.
